(19) United States
(12) Patent Application Publication
(10) Pub. No.: US 2016/0071803 A1
(43) Pub. Date: Mar. 10, 2016

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Tatsuro SAITO, Yokkaichi Mie (JP); Masayuki KITAMURA, Yokkaichi Mie (JP); Yuichi YAMAZAKI, Inagi Tokyo (JP); Akihiro KAJITA, Yokkaichi Mie (JP); Atsuko SAKATA, Yokkaichi Mie (JP); Tadashi SAKAI, Yokohama Kanagawa (JP)

(73) Assignee: KABUSHIKI KAISHA TOSHIBA, Tokyo (JP)

(21) Appl. No.: 14/645,268

(22) Filed: Mar. 11, 2015

(30) Foreign Application Priority Data
Sep. 9, 2014 (JP) 2014-183167

(51) Int. Cl. H01L 23/532; H01L 21/768; H01L 23/522

(52) U.S. Cl. CPC H01L 23/53276; H01L 23/5226; H01L 21/76843

(57) ABSTRACT

According to one embodiment, a semiconductor device is disclosed. The device includes a first interconnect, and an insulating film provided on the first interconnect, and being with a through hole communicating with the first interconnect. A catalyst layer is provided on the first interconnect of a bottom portion of the through hole. The catalyst layer has a form of a continuous film, and includes catalyst material and impurity. A first plug is provided in the through hole and is in contact with the catalyst layer, and includes a carbon nanotube layer. A second interconnect is disposed above the first interconnect and connected to the first interconnect via the first plug.

### CROSS-REFERENCE TO RELATED APPLICATIONS

This application is based upon and claims the benefit of priority from Japanese Patent Application No. 2014-183167, filed Sep. 9, 2014, the entire contents of which are incorporated herein by reference.

### FIELD

Embodiments described herein relate generally to a semiconductor device using a carbon nanotube and a method for manufacturing the same.

### BACKGROUND

There has been a proposal to use a carbon nanotube (CNT) layer as a plug in a via hole of multilayer interconnection. A process for forming the CNT layer includes, for example, forming a plurality of island-shaped catalyst layers and growing a carbon nanotube on each of the plurality of catalyst layers.

### BRIEF DESCRIPTION OF THE DRAWINGS

FIG. 1 is a sectional view schematically showing a semiconductor device according to a first embodiment;

FIG. 2 is a sectional view for explaining a method for manufacturing the semiconductor device according to the first embodiment;

FIG. 3 is a sectional view for explaining the method for manufacturing the semiconductor device according to the first embodiment following FIG. 2;

FIG. 4 is a sectional view for explaining the method for manufacturing the semiconductor device according to the first embodiment following FIG. 3;

FIG. 5 is a sectional view for explaining the method for manufacturing the semiconductor device according to the first embodiment following FIG. 4;

FIG. 6 is a sectional view for explaining the method for manufacturing the semiconductor device according to the first embodiment following FIG. 5;

FIG. 7 is a sectional view for explaining the method for manufacturing the semiconductor device according to the first embodiment following FIG. 6;

FIG. 8 is a sectional view for explaining the method for manufacturing the semiconductor device according to the first embodiment following FIG. 7;

FIG. 9 is a sectional view for explaining the method for manufacturing the semiconductor device according to the first embodiment following FIG. 8;

FIG. 10 is a sectional view schematically showing a semiconductor device according to a second embodiment;

FIG. 11 is a sectional view for explaining a method for manufacturing the semiconductor device according to the second embodiment;

FIG. 12 is a sectional view for explaining the method for manufacturing the semiconductor device according to the second embodiment following FIG. 11;

FIG. 13 is a sectional view for explaining the method for manufacturing the semiconductor device according to the second embodiment following FIG. 12;

FIG. 14 is a sectional view for explaining the method for manufacturing the semiconductor device according to the second embodiment following FIG. 13;

FIG. 15 is a sectional view schematically showing a semiconductor device according to a third embodiment;

FIG. 16 is a sectional view for explaining a method for manufacturing the semiconductor device according to the third embodiment;

FIG. 17 is a sectional view for explaining the method for manufacturing the semiconductor device according to the third embodiment following FIG. 16;

FIG. 18 is a sectional view for explaining the method for manufacturing the semiconductor device according to the third embodiment following FIG. 17;

FIG. 19 is a sectional view for explaining the method for manufacturing the semiconductor device according to the third embodiment following FIG. 18;

FIG. 20 is a sectional view schematically showing a semiconductor device according to a fourth embodiment;

FIG. 21 is a sectional view for explaining a method for manufacturing the semiconductor device according to the fourth embodiment;

FIG. 22 is a sectional view for explaining the method for manufacturing the semiconductor device according to the fourth embodiment following FIG. 21;

FIG. 23 is a sectional view for explaining the method for manufacturing the semiconductor device according to the fourth embodiment following FIG. 22;

FIG. 24 is a sectional view for explaining the method for manufacturing the semiconductor device according to the fourth embodiment following FIG. 23; and

FIG. 25 is an illustration showing a trial calculation of a ballistic length dependency of via resistance according to one embodiment.

### DETAILED DESCRIPTION

In general, according to one embodiment, a semiconductor device is disclosed. The device includes a first interconnect; and an insulating film provided on the first interconnect, and being with a through hole communicating with the first interconnect. A catalyst layer is provided on the first interconnect of a bottom portion of the through hole. The catalyst layer has a form of a continuous film, and includes catalyst material and impurity. A first plug is provided in the through hole and is in contact with the catalyst layer, and includes a carbon nanotube layer. A second interconnect is disposed above the first interconnect and connected to the first interconnect via the first plug.

In general, according to yet another embodiment, a method for manufacturing a semiconductor device is disclosed. The method includes forming an insulating film on a first interconnect; forming a through hole in the insulating film, the through hole communicating with the first interconnect; and forming a catalyst layer on the first interconnect of a bottom portion of the through hole, the catalyst layer, having a form of a continuous film, and including catalyst material and impurity. The method further includes forming a carbon nanotube layer by growing a carbon nanotube from the catalyst layer; and forming a second interconnect above the first interconnect, the second interconnect being connected to the first interconnect via the first plug.

Embodiments will be described hereinafter with reference to the accompanying drawings. In the drawings, the same numbers represent the same or corresponding portions, and overlapping explanations thereof will be made as necessary.

### First Embodiment

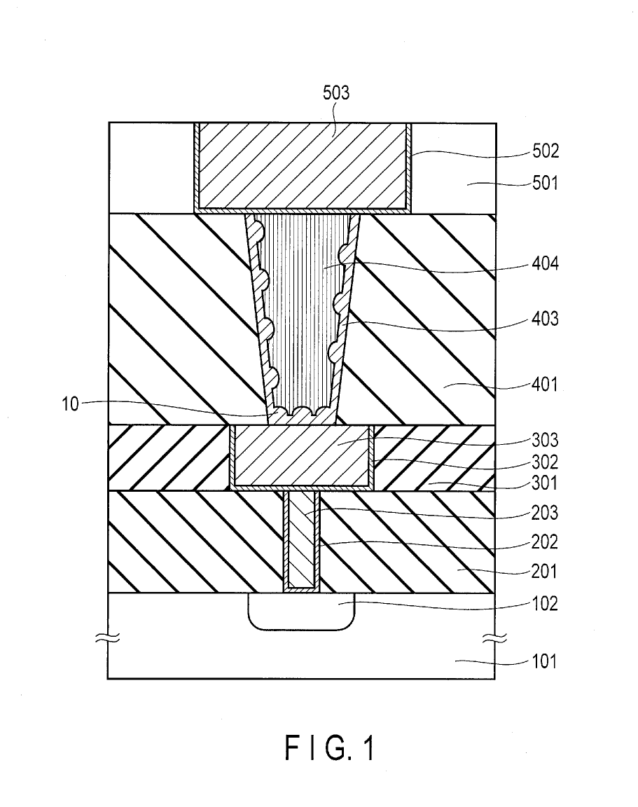

FIG. 1 is a sectional view schematically showing a semiconductor device of a present embodiment.

In the figure, 101 represents a substrate such as a silicon substrate or an SOI substrate, and a semiconductor element (not shown in the figure) such as a transistor or a capacitor is formed on the substrate 101. In the figure, 102 represents an impurity region formed on a surface of the substrate 101, which constitutes a part of the semiconductor element. The impurity region 102 is, for example, a source region or a drain region of a MOS transistor.

An interlayer insulating film 201 is provided on the substrate 101. A barrier metal film 202 and a contact plug 203 connected to the impurity region 102 are provided in the interlayer insulating film 201. The barrier metal film 202 covers a side surface and a bottom surface of the contact plug 203. The contact plug 203 is connected to the impurity region 102 via the barrier metal film 202.

An interlayer insulating film 301 is provided on the interlayer insulating film 201. A first barrier metal film 302 and a first interconnect 303 are provided in the interlayer insulating film 301. The first barrier metal film 302 covers a bottom surface and a side surface of the first interconnect 303. The first interconnect 303 is connected to the barrier metal film 202 and the contact plug 203 via the first barrier metal film 302.

An anti-diffusion layer may be provided on a top surface of the first interconnect 303. The anti-diffusion layer prevents diffusion of a metal material in the first interconnect 303. A material of the anti-diffusion layer includes, for example, silicon nitride or silicon carbide nitride.

An interlayer insulating film 401 is provided on the interlayer insulating film 301, the first barrier metal film 302, and the first interconnect 303. A catalyst layer 403 and a carbon nanotube layer (CNT layer) 404 as a via plug are provided in the interlayer insulating film 401. The catalyst layer 403 covers a side surface and a bottom surface of the CNT layer 404. The CNT layer 404 is connected to the first interconnect 303 via the catalyst layer 403. The via plug may further include a conductive layer other than the CNT layer 404.

The catalyst layer 403 has a function as a catalyst for growing a carbon nanotube. The catalyst layer 403 includes catalyst material and impurity.

The catalyst material includes, for example, at least one metal of Co, Ni, Fe, Ru and Cu. The catalyst material may include, for example, an alloy of at least one metal of Co, Ni, Fe, Ru and Cu. In addition, the catalyst material may include at least one of the above metals and further include at least one of the above alloys. As an alloy other than the catalyst materials, the catalyst layer 403 may include an alloy of at least one element of Si, Al, Mn, Zn, Ti, Cr, Au, Mo, W, Pd and Ag.

The impurity includes, for example, at least one element of O, N, F, P, S and Cl. In addition, the impurity may include carbide or nitride of the catalyst material and further include any of the above elements.

The catalyst layer 403 has a form of a continuous film, not a discontinuous film in a dispersed state. A surface of the catalyst layer 403 comprises recessed and projecting regions. The reference number 10 represents the projecting regions of the recessed and projecting regions.

The concentration of the impurity in the projecting regions 10 of the catalyst layer 403 is lower than those of the other regions of the catalyst layer 403. In other words, the concentration of the catalyst material of the projecting regions 10 is higher than those of the other regions. The projecting regions 10 may be regions of pure catalysts.

In the present embodiment, the entire bottom surface of the CNT layer 404 is covered with the catalyst layer 403. The entire bottom surface of the CNT layer 404 is connected to the first interconnect 303 (underlying conductive layer) via the catalyst layer 403.

On the other hand, in the case where the catalyst layer 403 is a discontinuous film, if a misalignment occurs between the CNT layer 404 and the first interconnect 303, a part of the bottom surface of the CNT layer 404 may not be connected to the first interconnect 303. This causes an increase in resistance at a portion (plug portion) of the CNT layer 404.

In the present embodiment, as described above, the catalyst layer 403 is a continuous film and the entire bottom surface of the CNT layer 404 is covered with the catalyst layer 403. Thus, even if the misalignment occurs between the CNT layer 404 and the first interconnect 303, the bottom surface of the CNT layer 404 is electrically connected to the first interconnect 303 via the catalyst layer 403. Therefore, an increase in resistance at the plug portion is suppressed.

A catalyst activation layer as a ground of a catalyst layer may be formed. The catalyst layer 403 of the present embodiment can also be formed, for example, as a thick continuous film which is 5 nm or more. When the catalyst layer 403 is thick, the catalyst activation layer may not be indispensable. When the catalyst activation layer is not formed, the volume of the CNT layer 404 can be increased accordingly, and the increase in resistance at the portion of the CNT layer 404 is suppressed.

In addition, even in the case where the catalyst activation layer is formed and the misalignment occurs between the CNT layer 404 and the first interconnect 303, the increase in resistance can be more suppressed in the case where the catalyst layer 403 is the continuous film than in the case where the catalyst layer 403 is the discontinuous film. That is, in the case where the catalyst layer 403 is the discontinuous film, the misalignment portion of the CNT layer 404 is electrically connected to the first interconnect 303 via the catalyst activation layer, which is a layer having higher resistance than the catalyst layer 403. On the other hand, in the case where the catalyst layer 403 is the continuous film, a large current flows through the catalyst layer 403, which is a layer having the lower resistance than the catalyst activation layer, and the misalignment portion of the CNT layer 404 is electrically connected to the first interconnect 303. Therefore, the increase in resistance can be suppressed.

An interlayer insulating film 501 is provided on the interlayer insulating film 401, the catalyst layer 403, and the CNT layer 404. A second barrier metal film 502 and a second interconnect 503 are provided in the interlayer insulating film 501. The second barrier metal film 502 covers a bottom surface and a side surface of the second interconnect 503. The second interconnect 503 is connected to the catalyst layer 403 and the CNT layer 404 via the second barrier metal film 502.

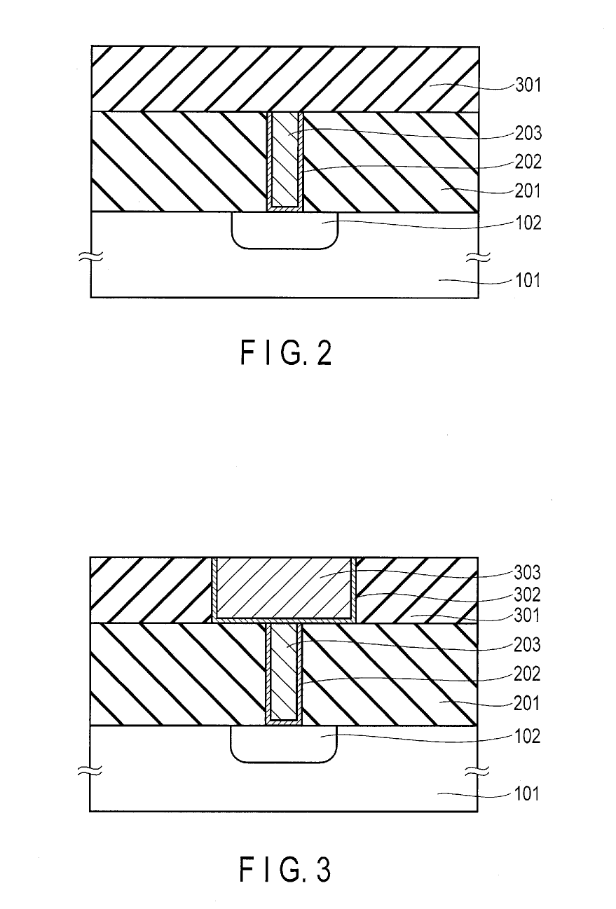

The semiconductor device of the present embodiment will be hereinafter further described in accordance with a method for manufacturing the same.

[FIG. 2]

The semiconductor element (not shown in the figure) such as a transistor or a capacitor is formed on the substrate 101 by a well-known process. The impurity region 102 is formed on the surface of the substrate 101 by the above process.

The interlayer insulating film 201 is formed on the substrate 101, subsequently a connection hole communicating with the impurity region 102 is formed in the interlayer insulating film 201, thereafter the connection hole is filled with the barrier metal film 202 and the contact plug 203.

A process for forming the barrier metal film 202 and the contact plug 203 includes, for example, a step of forming a barrier metal film on the entire surface to cover a bottom portion and a sidewall of the connection hole, a step of forming a conductive film on the barrier metal film to fill the connection hole, and a step of removing the barrier metal film and the conductive film outside the connection hole and planarizing their surfaces by chemical mechanical polishing (CMP) process.

A material of the barrier metal film 202 includes, for example, Ta, Ti, Ru, Co or Mn, or nitride or oxide of these elements. A material of the contact plug 203 includes, for example, W, Cu or Al. Depending on the material of the contact plug 203, the barrier metal film 202 can be omitted.

The interlayer insulating film 301 is formed on the interlayer insulating film 201 to cover the exposed surfaces of the barrier metal film 202 and the contact plug 203.

[FIG. 3]

Damascene interconnects (the first barrier metal film 302 and the first interconnect 303) connected to the barrier metal film 202 and the contact plug 203 are formed in the interlayer insulating film 301 by well-known damascene process. So-called RIE interconnects may be used instead of the damascene interconnects.

A material of the first barrier metal film 302 includes, for example, Ta, Ti, Ru, Co or Mn, or nitride or oxide of these elements. A material of the first interconnect 303 (interconnect material) includes, for example, a single metal of W, Cu or Al. Depending on the interconnect material, the first barrier metal film 302 can be omitted

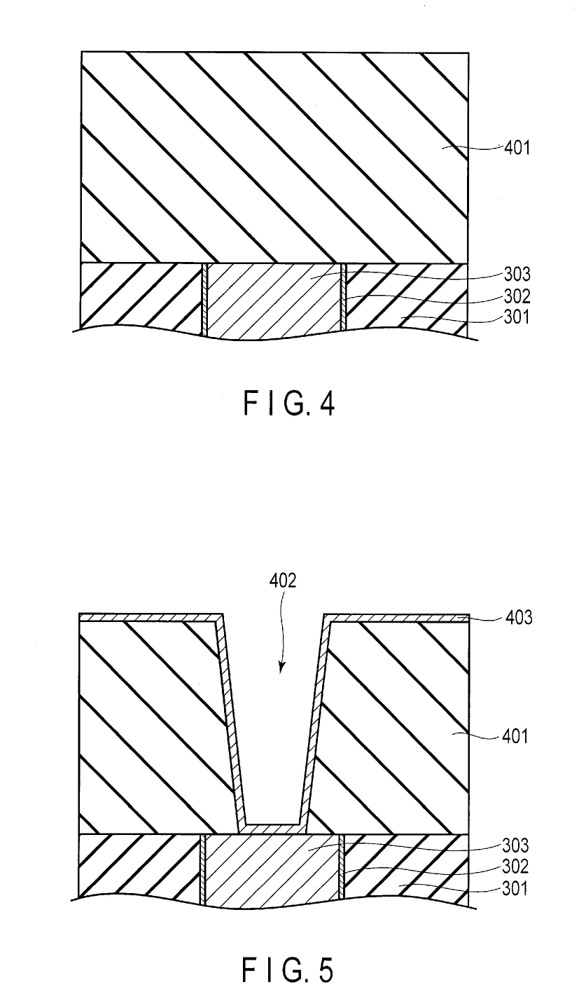

In the present embodiment, materials for the interlayer insulating films 201 and 301 are selected so that the etching rate of the interlayer insulating film 301 is sufficiently larger than the etching rate of the interlayer insulating film 201. When the etching rate of the interlayer insulating film 301 is not sufficiently larger than the etching rate of the interlayer insulating film 201, an etching stopper film (for example, an SiCN film) may be formed on the interlayer insulating film 201 as an underlying layer of the interlayer insulating film 301.

[FIG. 4]

The interlayer insulating film 401 is formed on the interlayer insulating film 301, the first barrier metal film 302, and the first interconnect 303. Before the interlayer insulating film 401 is formed, the above-described anti-diffusion layer may be formed on the interlayer insulating film 301, the first barrier metal film 302, and the first interconnect 303.

[FIG. 5]

By using a lithography process and an etching process, a via hole 402 is opened in the interlayer insulating film 401. Thereafter, the catalyst layer 403 for CNT growth is formed on the interlayer insulating film 401 to cover an inner surface (a sidewall and a bottom portion) of the via hole 402. The catalyst layer 403 is a single continuous layer. In this stage, there are no recessed and projecting regions on the surface of the catalyst layer 403.

The catalyst layer 403 is formed by using a CVD process, a sputtering process or a plating process. The catalyst layer 403 includes catalyst material and impurity. While a layer of the catalyst material is formed, the impurity may be added to the layer of the catalyst material. Alternatively, after the layer of the catalyst material is formed, the impurity may be added to the layer of the catalyst material.

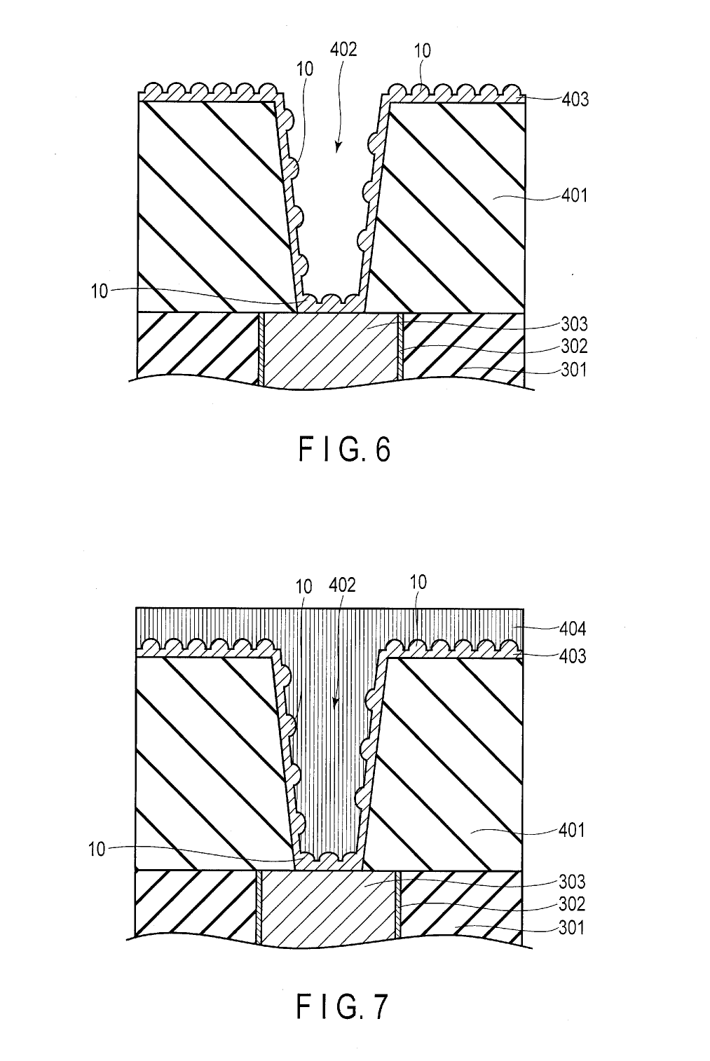

According to studies by inventors of the present embodiments, it has been made clear that when the concentration of the impurity in the catalyst layer 403 is less than or equal to 5%, the catalyst layer 403 having a form of a continuous film may not be formed. For example, a catalyst layer having a form of minute particles (dispersed state) is formed. In addition, it has also been made clear that if the concentration of impurities is less than or equal to 5%, CNTs do not grow and a graphene may grow, even if the catalyst layer has a form of a continuous layer. Therefore, it is desirable that the catalyst layer 403 have a concentration of impurities higher than 5%.

[FIG. 6]

The recessed and projecting regions are formed on the surface of the catalyst layer 403 by annealing treatment, for example, heat treatment in an inert gas such as nitrogen gas or argon gas. The concentration of the impurity in the projecting regions 10 of the recessed and projecting regions is lower than the concentration of the impurity in the recessed regions of the recessed and projecting regions. In other words, the concentration of the catalyst material in the projecting regions 10 is higher than the concentration of the catalyst material in the recessed regions. It is conceivable that the annealing treatment reduces or segregates the catalyst material of the surface of the catalyst layer 403 to form the projecting regions 10 with the high catalyst material concentration. When the concentration of catalyst material in the projecting regions 10 is high, the projecting regions 10 of the easily moves, so that the projecting regions 10 function as catalysts for the CNTs. According to studies by the inventors of the present embodiments, it has been made clear that the CNTs can be easily grown, when the height of the projecting regions 10 (the roughness of the recessed and projecting regions) is greater than or equal to approximately 10 nm.

It is noted that, even if the surface of the catalyst layer 403 lacks the recessed and projecting regions, if the surface of the catalyst layer 403 is provided with a plurality of regions having the high catalyst material concentrations, the plurality of regions function as the catalysts for the CNTs. Such regions having the high concentration catalyst material can also be formed by the annealing treatment.

[FIG. 7]

The CNTs are grown from the catalyst layer 403 (the projecting regions 10) by CVD process, and the CNT layer 404 having a thickness which fills the via hole 402 is formed. In the above CVD process, for example, hydrocarbon-based gas such as gaseous methane or acetylene, or a gaseous mixture thereof is used as for a source gas of carbon. Further, for example, hydrogen or a noble gas is used as a carrier gas. In addition, the CVD process for growing the above the CNTs (C-CVD process) is performed, for example, at a temperature of 600 to 700° C. When high energy is imparted to the source gas by using plasma, the C-CVD process can be performed at a temperature lower than 600° C.

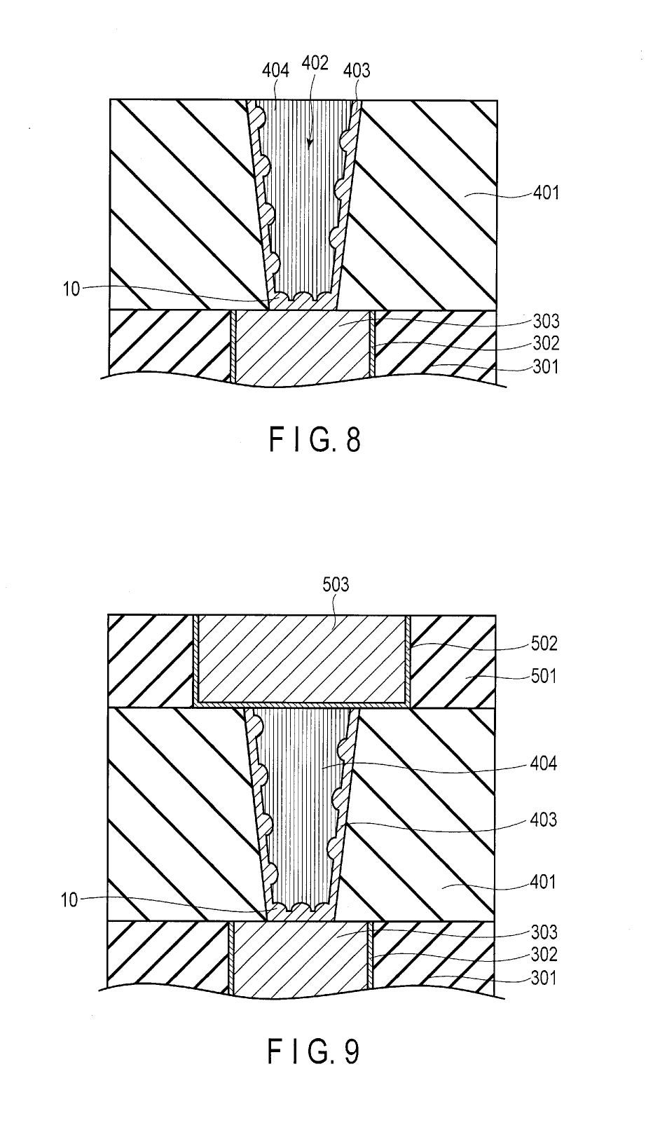

It is noted that, when the C-CVD process with the source gas being imparted with the sufficiently high energy, for example, the C-CVD process at a high temperature higher than 700° C. is adopted, the above C-CVD process can concurrently serve as the annealing treatment of FIG. 6. In this case, the annealing process of FIG. 6 can be omitted and the number of steps can be reduced. In addition, the annealing process of FIG. 6 can also be omitted when the sufficiently high energy is imparted to the source gas using plasma at the time of the C-CVD process.

[FIG. 8]

The catalyst layer and the CNT layer outside the via hole 402 are removed and their surfaces are planarized by CMP process. As a result, a plug structure including the catalyst layer 403 covering the inner surface (the sidewall and the bottom portion) of the via hole 402, and the CNT layer 404 which fills the via hole 402 through the catalyst layer 403 can be obtained. Thereafter, SiO₂ or metal may be impregnated in the CNT layer 404 in order to fix the CNT layer 404.

[FIG. 9]

The interlayer insulating film 501 is formed on the interlayer insulating film 401, the catalyst layer 403, and the CNT layer 404, thereafter the damascene interconnects (the second barrier metal film 502 and the second interconnect 503) are formed in the interlayer insulating film 501 by damascene process. The second interconnect 503 is connected to the catalyst layer 403 and the CNT layer 404 via the second barrier metal film 502. So-called RIE interconnects may be used instead of the damascene interconnects.

### Second Embodiment

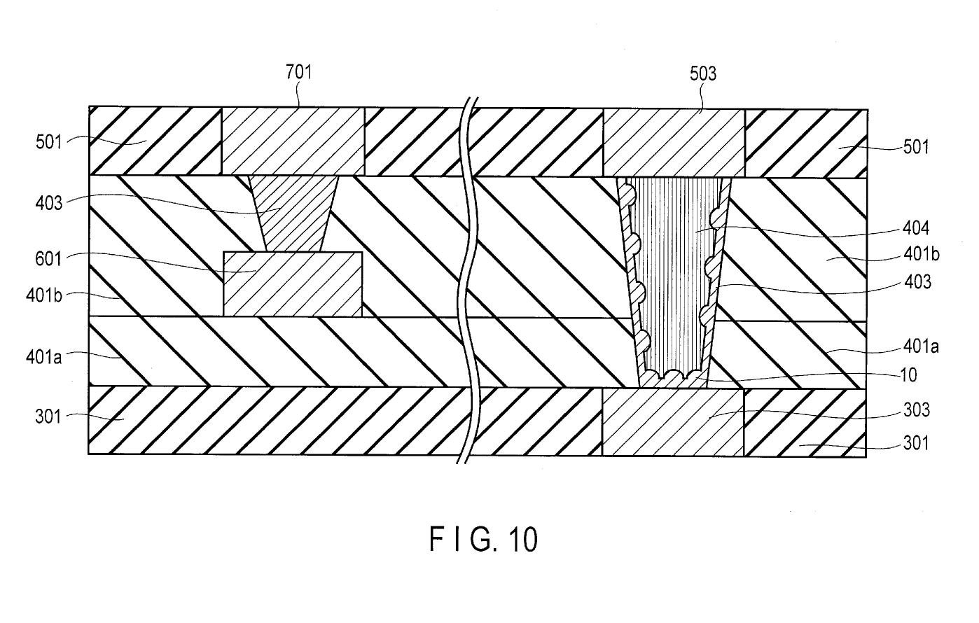

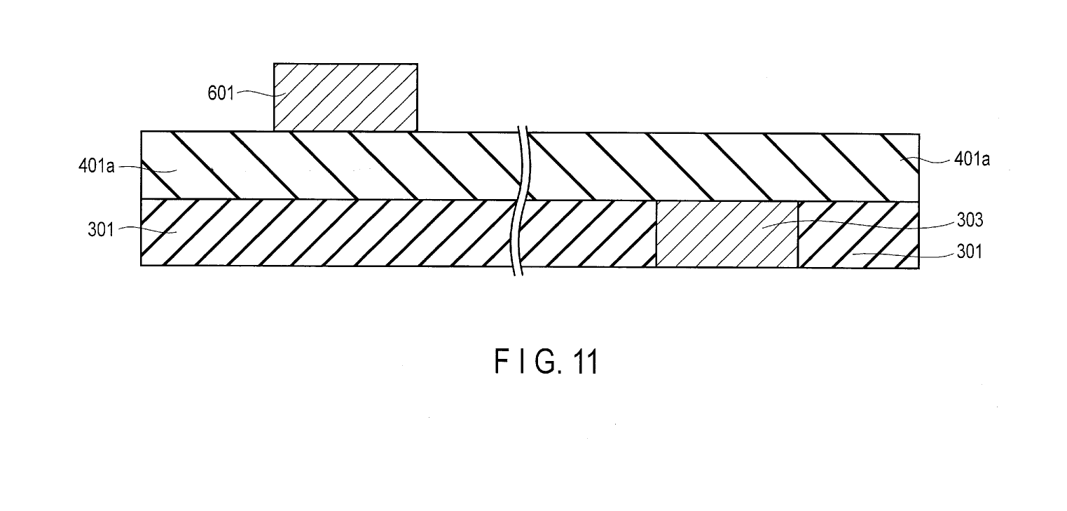

FIG. 10 is a sectional view schematically showing a semiconductor device of a present embodiment. FIG. 11 to FIG. 14 are sectional views for explaining a method for manufacturing the semiconductor device of the present embodiment. In the following embodiment, barrier metal films are omitted for the sake of simplicity. Moreover, structures located under an interlayer insulating film 301 are also omitted.

In the present embodiment, the case of a semiconductor device including via plugs differing in height will be described. In FIG. 10 to FIG. 14, a right side of a break line shows multilayer interconnection including a high via plug, and a left side of the break line shows multilayer interconnection including a low via plug. In the following description, the right side and the left side of the break line are referred to as a high via region and a low via region, respectively.

FIG. 25 shows a trial calculation of a ballistic length dependency of resistance of a via plug (via resistance).

In FIG. 25, the cases where the numbers N of layers of a multiwall carbon nanotube are 4, 8, 16, 32 and 64 are cited as examples, and the figure shows carbon nanotube via resistance in the case where the diameter of a via plug (via diameter) is 80 nm, the height h is 2400 nm, and the aspect ratio (A/R) is 30 on the premise that carbon nanotubes are packed closest. In addition, W (tungsten) used as the usual material of a via plug (via material) is cited for comparison target.

As shown in FIG. 25, in carbon nanotubes of any of the numbers N, as the ballistic length becomes longer, the via resistance decreases. On the other hand, the via resistance of W is constant (approximately 300Ω) independently of the length.

From this relationship, it is understood that when the ballistic length is 500 nm or more, the via resistance of the carbon nanotubes with about 16 to 32 layers, which are considered to be capable of being stably independent even over large length, becomes lower than the via resistance of W.

Thus, based on the ballistic length dependency of the via resistance of the carbon nanotube, it is effective to form a carbon nanotube via for a via with a height of 500 nm or more. On the other hand, as regards a via with a height of less than 500 nm (e.g. via diameter=80 nm, A/R=6), the via resistance of the carbon nanotube is constant (e.g. 6450Ω/number of nanotubes·number of layers), and the resistance of the W via becomes lower.

As has been described above, when the carbon nanotube with the ballistic length of 500 nm is used, the carbon nanotube can make the resistance lower than the conventional metal material as regards the via with the via height of 500 nm or more. However, when the via height is less than 500 nm, the resistance becomes constant since there is no scattering of electrons in the carbon nanotube. Thus, in the case of the carbon nanotube, compared to the metal via, it becomes difficult to reduce the resistance as the via height becomes smaller. Therefore, as regards the via height of less than 500 nm, the conventional metal material is more effective than the carbon nanotube in reducing the resistance.

Thereupon, in the present embodiment, a CNT layer 404 is used for a high via plug (first plug) which is greater than or equal to 500 nm in height, and a catalyst layer 403 is used for a low via plug (second plug) which is less than 500 nm in height. Such multilayer interconnection including via plugs differing in height is used, for example, for a semiconductor storage device in which memory cells are three-dimensionally arranged.

Next, an example of the method for manufacturing the semiconductor device of the present embodiment will be described.

[FIG. 11]

The steps up to the step of FIG. 2 of the first embodiment are carried out, thereafter a first interconnect 303 is formed in the high via region. Subsequently, an interlayer insulating film 401a is formed on the high via region and the low via region, thereafter a third interconnect 601 is formed on the interlayer insulating film 401a of the low via region.

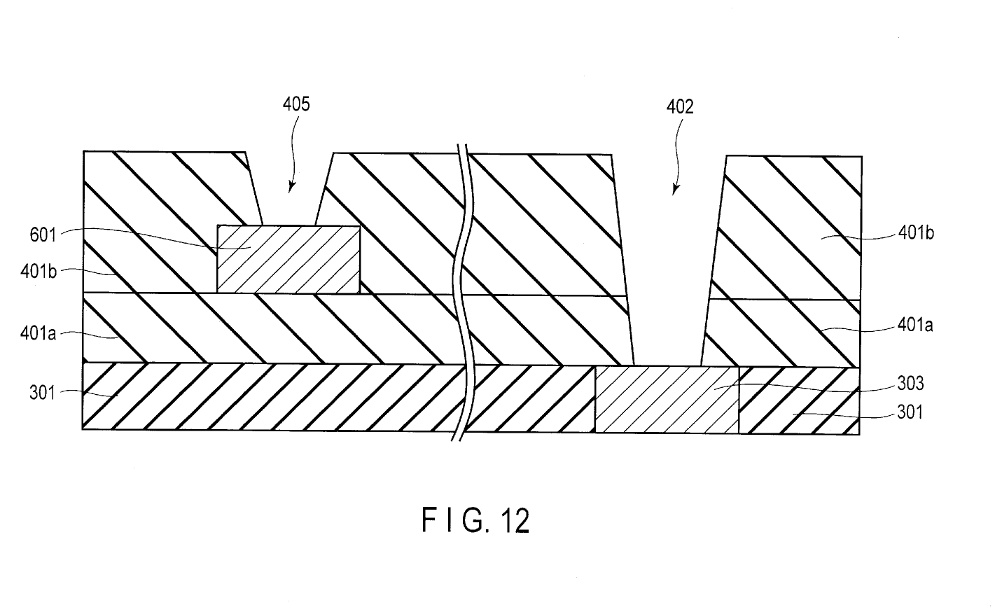

A step of forming the third interconnect 601 includes a step of forming a conductive film to be processed into the third interconnect 601 and a step of processing the conductive film in the form of an interconnect by using reactive ion etching (RIE) process. The third interconnect 601 is a so-called RIE interconnect, but the third interconnect 601 may be a damascene interconnect.

[FIG. 12]

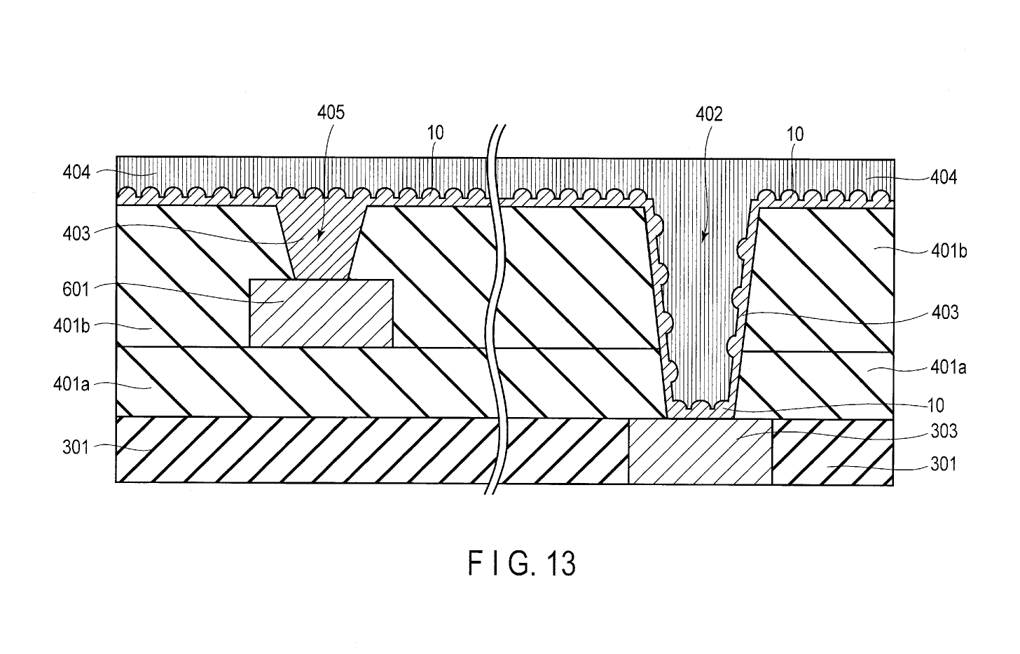

An interlayer insulating film 401b is formed on the interlayer insulating film 401a to cover the third interconnect 601, thereafter a via hole 405 communicating with the third interconnect 601 is opened in the interlayer insulating film 401b, and a via hole 402 communicating with the first interconnect 303 is opened in the interlayer insulating films 402a and 401a. The via hole 405 is shallower than the via hole 402. The depth of the via hole 405 is less than 500 nm, and the depth of the via hole 402 is greater than or equal to 500 nm.

[FIG. 13]

The catalyst layer 403 is formed on the interlayer insulating films 401a and 401b to fill the shallow via hole 405 and cover an inner surface (a sidewall and a bottom portion) of the via hole 402. The catalyst layer 403 in the via hole 405 is used as a via plug. Thereafter, the CNTs are grown from the catalyst layer 403 (projecting regions 10) by CVD process, and the CNT layer 404 having a thickness which fills the via hole 402 is formed.

According to the present embodiment, the CNTs can be grown on the catalyst layer 403 having the form of the continuous film, so that the thick catalyst layer 403 as the second via plug can be formed in the via hole 405 while the second via plug does not lose the function as a catalyst for the CNTs.

On the other hand, in the case where a discontinuous film (a plurality of films) is used as a catalyst layer, when the thickness of the catalyst layer exceeds a predetermined level, the catalyst layer cannot take the form of the discontinuous film, and a layer having a form in which a plurality of films are joined is formed. Such a layer functions as a catalyst for graphene, not the CNTs, so that the layer cannot be used as a catalyst layer of the CNTs. When the discontinuous film is used as the catalyst layer of the CNTs, there is a limit on the thickness of the catalyst layer. Therefore, when the catalyst layer having such a thickness as fills the via hole 405 is formed, a catalyst layer having such a thickness as functions as the catalyst for the graphene, not the CNTs, may be formed in the via hole 402.

Therefore, when the discontinuous film (plurality of films) is used as a catalyst layer, it is difficult to form the thick catalyst layer as a via plug in the via hole 405 while the catalyst layer in the via hole 402 does not lose the function as a catalyst for the CNTs.

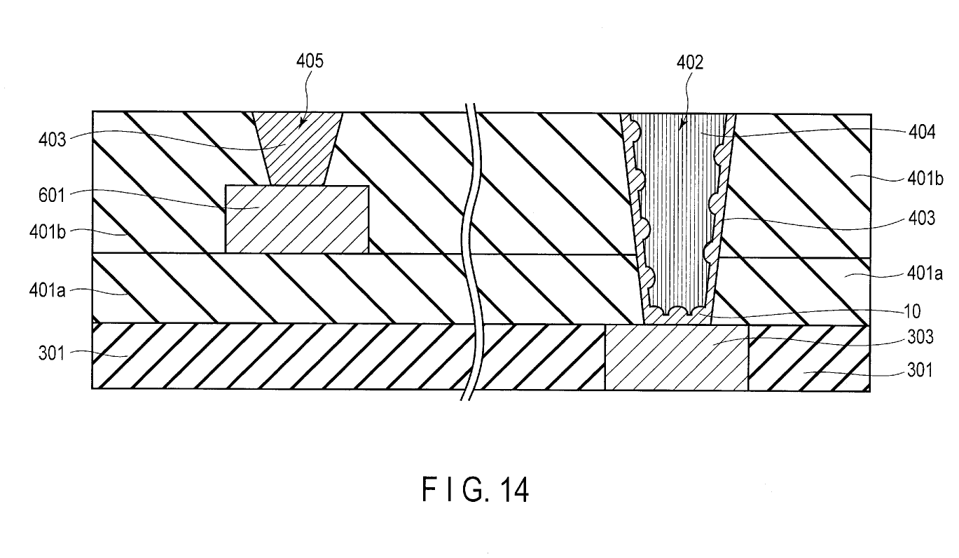

It is noted that, to prevent the whole interior of the via hole 402 from being filled with the catalyst layer 403, for example, it is also possible to form a metal film on the bottom portion of the via hole 402, thereafter selectively grow the catalyst layer 403 from the metal film by CVD process. In this case, the sidewall of the via hole 402 is not covered with the catalyst layer 403. If the catalyst layer 403 is on the bottom portion of the via hole 402, the CNTs grow from the bottom portion of the via hole 402 toward an opening surface, and thus, the CNT layer 404 is formed.

[FIG. 14]

The catalyst layer outside the via holes 402 and 405 are removed and their surfaces are planarized by CMP process. As a result, a high plug structure including the catalyst layer 403 and the CNT layer 404 is formed in the high via region, and a low plug structure including the catalyst layer 403 but not including the CNT layer 404 is formed in the low via region. In this manner, according the present embodiment, plug structures differing in height can be formed all together in the same step.

After that, an interlayer insulating film 501, a second interconnect 503, and a fourth interconnect 701 are formed by well-known process, and the semiconductor device shown in FIG. 10 is obtained.

### Third Embodiment

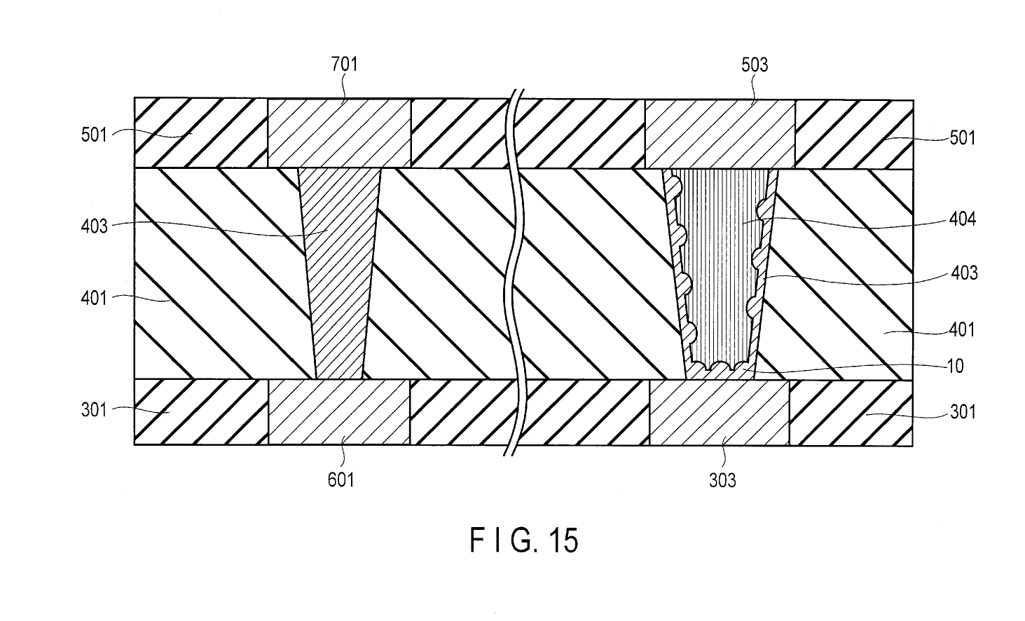

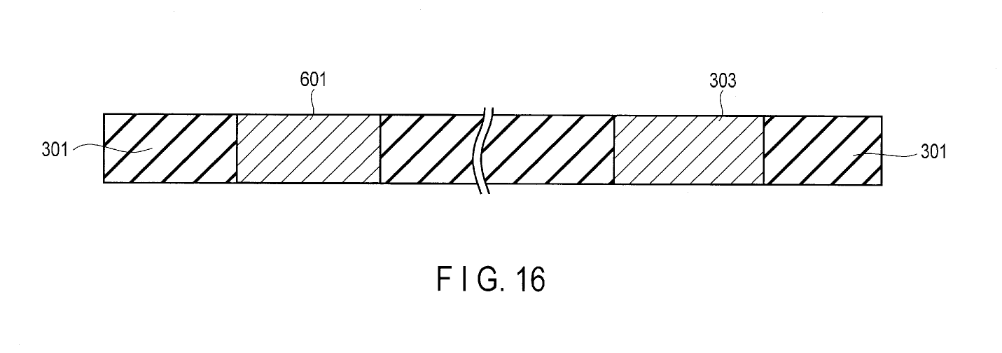

FIG. 15 is a sectional view schematically showing a semiconductor device of a present embodiment. FIG. 16 to FIG. 19 are sectional views for explaining a method for manufacturing the semiconductor device of the present embodiment.

In the present embodiment, the case of a semiconductor device comprising plugs which are the same in height but differ in diameter will be described. In FIG. 15 to FIG. 19, the right side of a break line shows multilayer interconnection including a via plug which is large in diameter, and the left side of the break line shows multilayer interconnection including a via plug which is small in diameter. In the following description, the right side and the left side of the break line are referred to as a large-via-diameter region and a small-via-diameter region, respectively.

A catalyst layer is formed on a sidewall of a via hole. An underlying layer may be further formed on the sidewall of the via hole. A material of the underlying layer is, for example, a metal such as Ta, Ti, Ru, W or Al, or nitride or oxide of these metals. The underlying layer may have a lamination structure including the above material.

When the catalyst layer and the underlying layer are formed on the sidewall of the via hole, the diameter of a CNT layer formed in the via hole must be less than the diameter of the via hole. In a CNT comprising a single-layer graphene sheet in the form of a coaxial tube, only one third of the structure of the graphene sheet shows metallic electrical properties. To make most of the CNT show metallic electrical properties, it is necessary to use a CNT comprising a multilayer graphene sheet in the form of a coaxial tube. The outer diameter of the multilayer CNT layer is greater than or equal to 20 nm.

In the case where the diameter of the via hole is 60 nm (in the case of a small via diameter), when the total thickness of the catalyst layer and the underlying layer formed on the sidewall of the via hole is approximately 20 nm, the diameter of the CNT layer formed in the via hole is approximately 20 nm. In this case, the number of CNTs formed in the via hole which contribute to electron conduction is a few.

Therefore, in the case of a small via diameter, if the number of CNTs constituting a via plug differs from a predetermined number even by one, the resistance of the via plug greatly varies. When a plurality of via plugs of small via diameter are formed, variations in resistance are easily caused.

Thereupon, in the present embodiment, as a via plug (third plug) of small diameter, not a CNT layer 404 but a catalyst layer 403 (metal layer) is used. As a via plug of large diameter, the CNT layer 404 is used. Such multilayer interconnection including via plugs differing in diameter is used, for example, for a semiconductor storage device in which memory cells are three-dimensionally arranged.

Next, an example of the method for manufacturing the semiconductor device of the present embodiment will be described.

[FIG. 16]

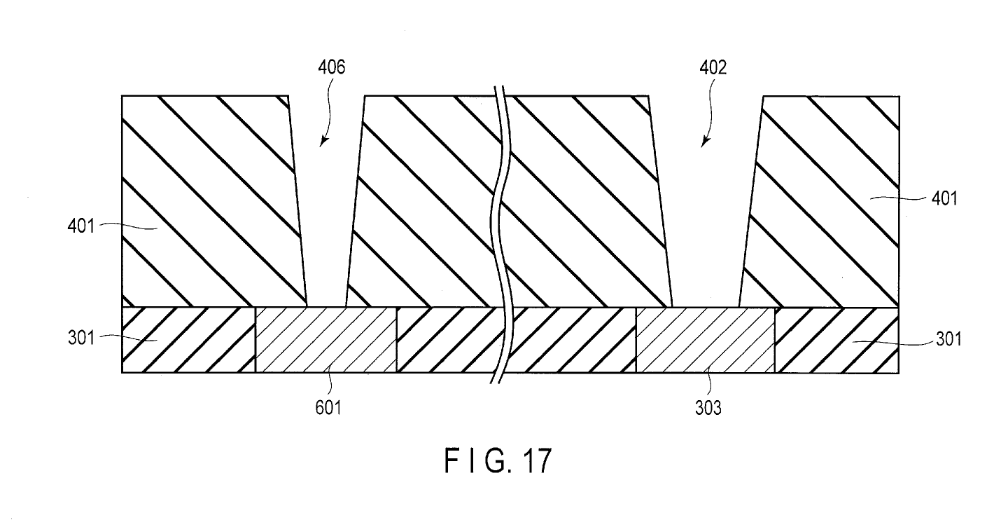

The steps up to the step of FIG. 2 of the first embodiment are carried out, thereafter a first interconnect 303 and a third interconnect 601 are formed in the interlayer insulating film 301 of the large-via-diameter region and the small-via-diameter region, respectively.

[FIG. 17]

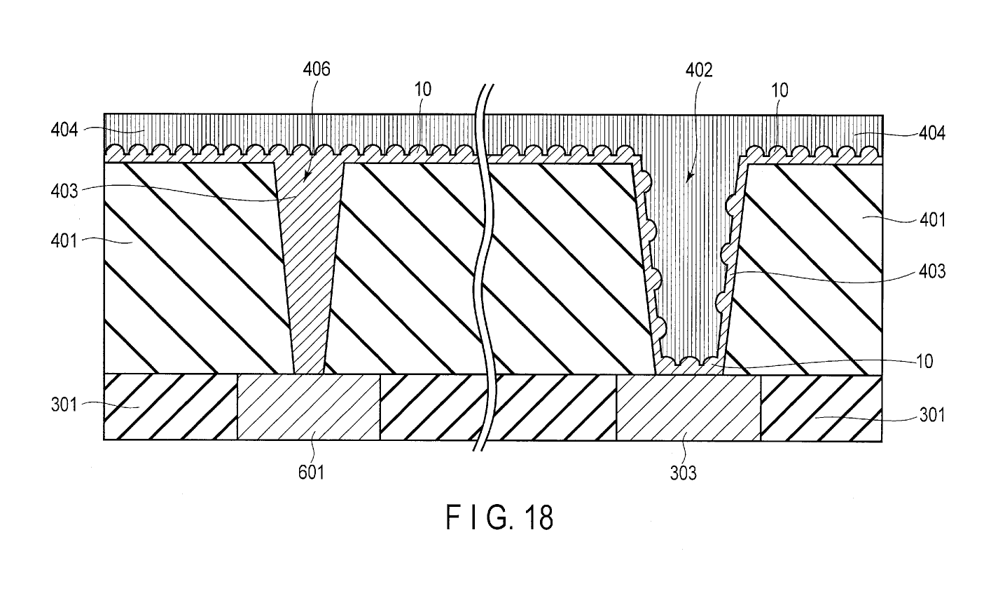

An interlayer insulating film 401 is formed on the large-via-diameter region and the small-via-diameter region, thereafter a via hole 402 communicating with the first interconnect 303 of the large-via-diameter region and a via hole 406 communicating with the third interconnect 601 of the small-via-diameter region are formed in the interlayer insulating film 401. The aspect ratio of the via hole 406 is higher than that of the via hole 402.

[FIG. 18]

The catalyst layer 403 is formed on the interlayer insulating film 401 to fill the via hole 406 of a high aspect ratio and cover an inner surface (a sidewall and a bottom portion) of the via hole 402. The catalyst layer 403 in the via hole 406 is used as a via plug (third plug). The catalyst layer 403 including a small void may be formed in the via hole 406. Even the catalyst layer 403 like this does not have any problem as a via plug.

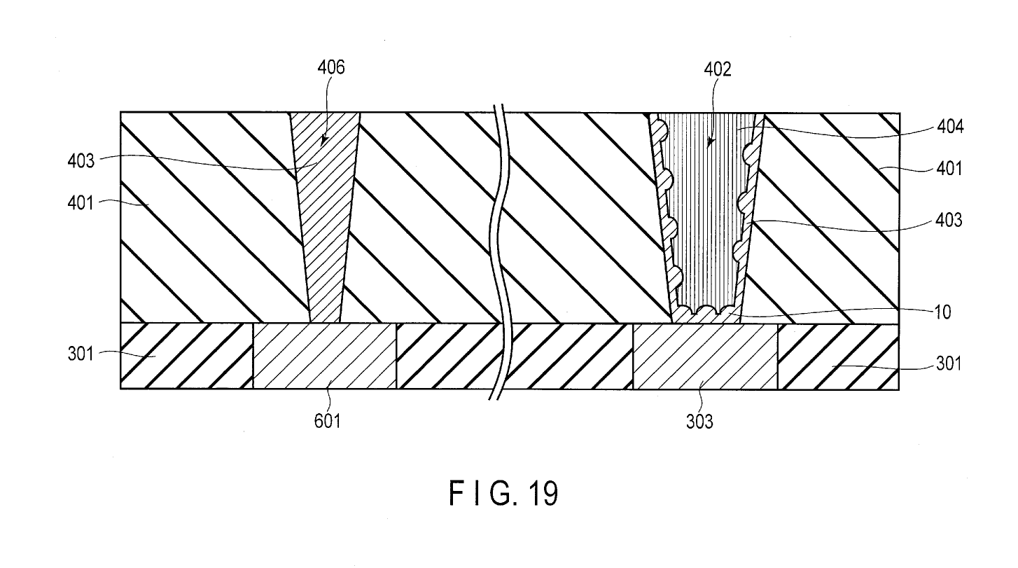

Thereafter, the CNTs are grown from the catalyst layer 403 by CVD process, and the CNT layer 404 having a thickness which fills the via hole 402 is formed.

[FIG. 19]

The catalyst layer outside the via holes 402 and 406 are removed and its surface is planarized by CMP process. As a result, a plug structure of large diameter including the catalyst layer 403 and the CNT layer 404 is formed in the large-via-diameter region, and a plug structure of small diameter including the catalyst layer 403 but not including the CNT layer 404 is formed in the small-via-diameter region. In this manner, according to the present embodiment, plug structures differing in diameter can be formed all together in the same step.

After that, an interlayer insulating film 501 and a second interconnect 503 are formed by well-known process, and the semiconductor device shown in FIG. 15 is obtained.

Even if there are plugs differing in height and plugs differing in diameter, these plugs can be formed all together in the same step by combining the second and third embodiments.

### Fourth Embodiment

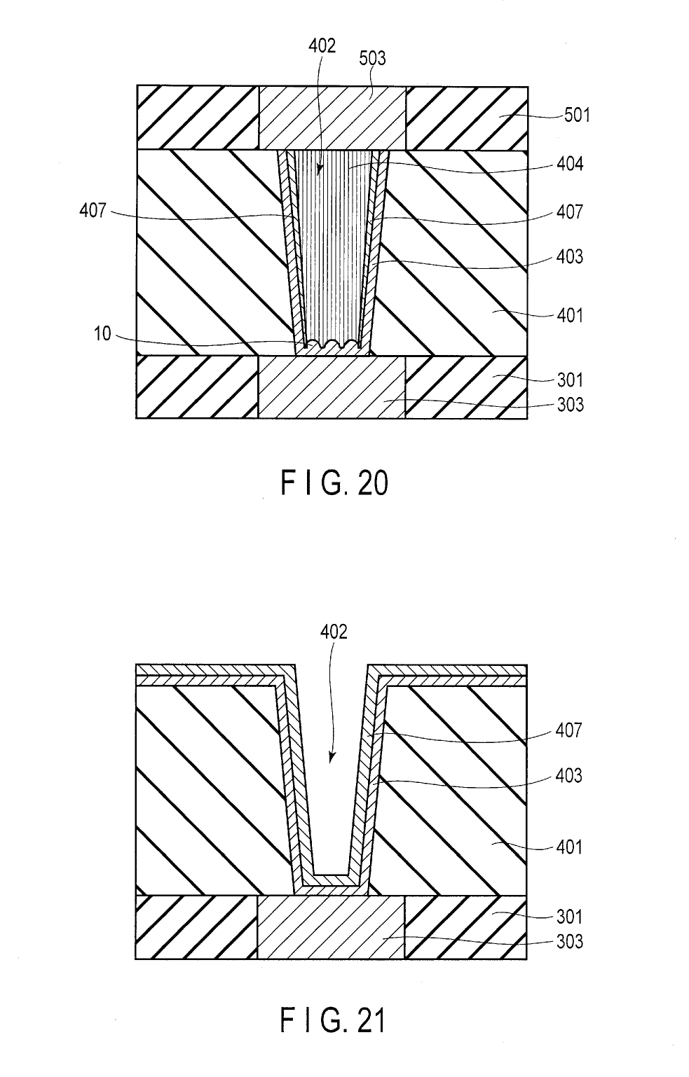

FIG. 20 is a sectional view schematically showing a semiconductor device of a present embodiment. FIG. 21 to FIG. 24 are sectional views for explaining a method for manufacturing the semiconductor device of the present embodiment.

The present embodiment differs from the first embodiment in that a CNT growth suppression film 407 which suppresses the growth of the CNTs is provided on a catalyst layer 403 on a sidewall of a via hole 402.

As a result, although the CNTs grow from a bottom portion of the via hole 402 in a direction toward an opening surface of the via hole 402 (upward direction), the growth of the CNTs from the sidewall of the via hole 402 in a diameter direction (horizontal direction) is suppressed. In this manner, in the present embodiment, because a decrease in the diameter (width) of the via hole 402 due to the CNTs growing in the horizontal direction is suppressed, a decrease in the number of the CNTs growing from the bottom portion of the via hole 402 to the opening surface of the via hole 402 is suppressed. An increase in the resistance of the CNT layer 404 is thereby suppressed.

Next, an example of the method for manufacturing the semiconductor device of the present embodiment will be described.

[FIG. 21]

After the step of FIG. 5 of the first embodiment, the CNT growth suppression film 407 is formed on the catalyst layer 403. The catalyst layer 403 on the bottom portion and the sidewall of the via hole 402 is covered with the CNT growth suppression film 407. In addition, the catalyst layer 403 outside the via hole 402 is also covered with the CNT growth suppression film 407.

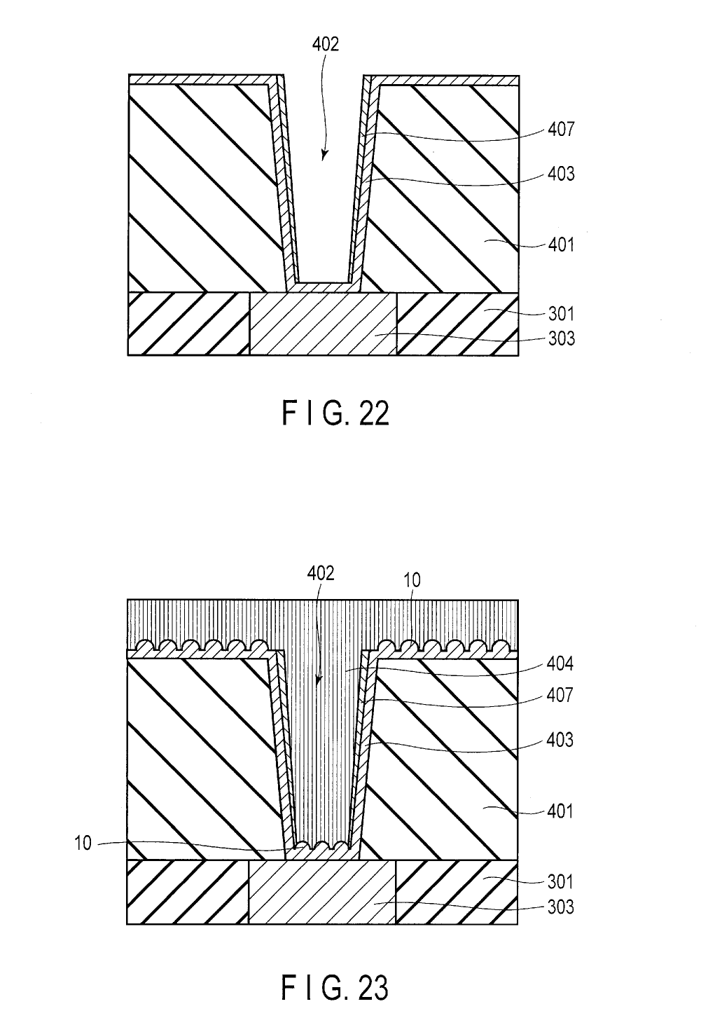

A material of the CNT growth suppression film 407 is a material which does not serve as a catalyst for the CNTs, and includes, for example, at least one element of W, Ti, Al and Si, or an alloy, nitride or oxide of the at least one element. When a conductive material (for example, W, Ti or Al) is used as the material of the CNT growth suppression film 407, an increase in resistance at a plug portion is suppressed.

[FIG. 22]

The CNT growth suppression film covering the catalyst layer 403 on the bottom portion of the via hole 402 and the CNT growth suppression film covering the catalyst layer 403 outside the via hole 402 are selectively removed by etching back.

When the catalyst layer 403 is formed thickly, the etch-back process margin can be increased. That is, the removal of the catalyst layer 403 of the bottom portion of the via hole 402 due to etching back can be suppressed.

[FIG. 23]

Recessed and projecting regions are formed on a surface of the catalyst layer 403 by annealing process, thereafter the CNTs are grown from the catalyst layer 403 by CVD process, and the CNT layer 404 having a thickness which fills the via hole 402 is formed. At this time, the CNTs grow from projecting regions 10 of the catalyst layer 403 of the bottom portion of the via hole 402 and projecting regions 10 of the catalyst layer 403 outside the via hole 402.

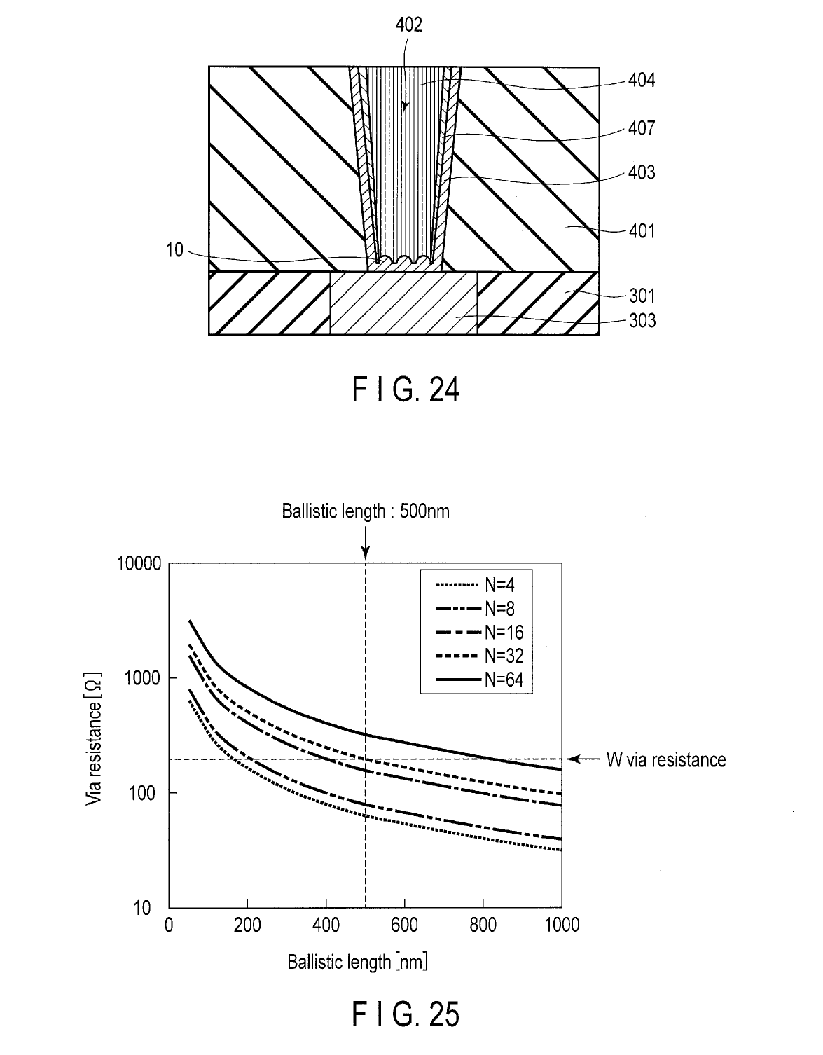

It is noted that, although projecting regions (not shown in the figure) may occur also on the catalyst layer 403 on the sidewall of the via hole 402 by annealing process, the catalyst layer 403 of the above portion is covered with the CNT growth suppression film 407, and thus, the growth of the CNTs from the catalyst layer 403 of the above portion is suppressed.

[FIG. 24]

The catalyst layer and the CNT layer outside the via hole 402 are removed and their surfaces are planarized by CMP process.

After that, an interlayer insulating film 501 and a second interconnect 503 are formed by well-known process, and the semiconductor device shown in FIG. 20 is obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first interconnect;
an insulating film provided on the first interconnect, and being with a through hole communicating with the first interconnect;
a catalyst layer provided on the first interconnect of a bottom portion of the through hole, having a form of a continuous film, and including catalyst material and impurity;
a first plug provided in the through hole and being in contact with the catalyst layer, the first plug comprising a carbon nanotube layer; and
a second interconnect disposed above the first interconnect and connected to the first interconnect via the first plug.

2. The device according to claim 1, wherein the catalyst layer is further provided on a sidewall of the through hole.

3. The device according to claim 1, wherein a surface of the catalyst layer comprises a plurality of regions differing in a concentration of the impurity.

4. The device according to claim 1, wherein a surface of the catalyst layer includes a recessed and projected region, and a concentration of the impurity in a projected region of the recessed and projected region is lower than a concentration of the impurity of in a recessed region of the recessed and projected region.

5. The device according to claim 1, wherein a surface of the catalyst layer of the bottom portion of the through hole includes the recessed and projected regions.

6. The device according to claim 4, wherein a concentration of the catalyst material in the projected region is higher than a concentration of the catalyst material in the recessed region.

7. The device according to claim 1, further comprising:
a third interconnect;
a fourth interconnect provided above the third interconnect; and
a second plug connecting the third interconnect and the fourth interconnect, the second plug being smaller in height than the first plug,
wherein a material of the second plug is same to a material of the catalyst layer.

8. The device according to claim 1, further comprising:
a third interconnect;
a fourth interconnect provided above the third interconnect; and
a third plug connecting the third interconnect and the fourth interconnect, the third plug being smaller in diameter than the first plug,
wherein a material of the third plug is same to a material of the catalyst layer.

9. The device according to claim 8, wherein the first plug and the third plug are same in height.

10. The device according to claim 2, further comprising a growth suppression film selectively provided on the catalyst layer on the sidewall of the through hole, the growth suppression film suppressing growth of a carbon nanotube.

11. The device according to claim 1, further comprising:
a first barrier metal film covering a side surface and a bottom surface of the first interconnect; and
a second barrier metal film covering a side surface and a bottom surface of the second interconnect.

12. The device according to claim 1, wherein the impurity includes at least one element of O, N, F, P, S and Cl.

13. The device according to claim 1, wherein the first and second interconnects are each a damascene interconnect.

14. A method for manufacturing a semiconductor device comprising:
forming an insulating film on a first interconnect;
forming a through hole in the insulating film, the through hole communicating with the first interconnect;
forming a catalyst layer on the first interconnect of a bottom portion of the through hole, the catalyst layer, having a form of a continuous film, and including catalyst material and impurity;
forming a first plug in the through hole by growing a carbon nanotube from the catalyst layer; and
forming a second interconnect above the first interconnect, the second interconnect being connected to the first interconnect via the first plug.

15. The method according to claim 14, wherein a surface of the catalyst layer comprises a plurality of regions differing in a concentration of the impurity.

16. The method according to claim 14, further comprising performing heat treatment for the catalyst layer, and wherein after performing the heat treatment, a surface of the catalyst layer comprises a plurality of regions differing in a concentration of the impurity.

17. The method according to claim 14, wherein the carbon nanotube is grown by CVD process using a source gas including carbon.

18. The method according to claim 14, wherein the catalyst layer is further formed on a sidewall of the through hole in the forming the catalyst layer, the method further comprising:
forming a growth suppression film on the catalyst layer, the growth suppression film suppressing growth of a carbon nanotube; and
selectively leaving the growth suppression film on the sidewall of the through hole by etching back the growth suppression film, and forming the growth suppression film, wherein the selectively leaving the growth suppression film is performed after the forming the catalyst layer and before the growing the carbon nanotube.

19. The method according to claim 14, further comprising forming a second plug which includes a material of the catalyst layer and is smaller in height than the first plug.

20. The method according to claim 14, further comprising forming a third plug which includes a material of the catalyst layer and is smaller in diameter than the first plug.
